(19) United States
(12) Patent Application Publication
(10) Pub. No.: US 2026/0035312 A1
(43) Pub. Date: Feb. 5, 2026

(54) SUBSTRATE COMPRISING TANTALUM COATING

(71) Applicant: SGL CARBON SE, Wiesbaden (DE)

(72) Inventors: Christian THIELEMANN, Meitingen (DE); Charles WIJAYAWARDHANA, Meitingen (DE); Urban FORSBERG, Sturefors (SE); Henrik PEDERSEN, Stigtomta (SE)

(73) Assignee: SGL CARBON SE, Wiesbaden (DE)

(21) Appl. No.: 18/998,823

(22) PCT Filed: Jul. 5, 2023
(86) PCT No.: PCT/EP2023/068503

§ 371 Date: Jan. 27, 2025

(30) Foreign Application Priority Data
Jul. 29, 2022 (DE) 102022207893.4

(51) Int. Cl. C04B 41/50; C04B 41/00; C04B 41/45; C04B 41/87; C30B 35/00

(52) U.S. Cl. CPC C04B 41/5057; C04B 41/009; C04B 41/4531; C04B 41/457; C04B 41/87; C30B 35/002; C04B 2235/3839

(57) ABSTRACT

A gas-phase deposition process for coating a carbonaceous substrate with a tantalum carbide coating, the process includes a coating step. The coating step includes placing a carbonaceous substrate into a reaction chamber, heating the reaction chamber to a temperature between about 1100° C. to about 1500° C. for a duration of between about 1 h to about 24 h. The coating step further includes supplying a process gas to the reaction chamber, the process gas includes a halide containing species and for at least 15 minutes after the start of the process, the process gas includes less than 4 at.-% of carbon and less than 10 vol.-% of H₂. Further, the coating step includes supplying a tantalum containing species to the reaction chamber, or placing a solid comprising tantalum into the reaction chamber. Alternatively, the process includes placing a solid with a tantalum halide into the reaction chamber.

### TECHNICAL FIELD

The present invention relates to the field of tantalum carbide coated substrates. More specifically, the present invention relates to carbonaceous substrates coated with a tantalum carbide coating.

### BACKGROUND

Due to their high temperature resistance, specifically the high melting point and thermal conductivity, as well as low coefficient of thermal expansion, graphite materials may be used in numerous high-temperature processes. Further, graphite may be used as a susceptor. A susceptor may absorb electromagnetic energy and convert it to heat or re-emit the electromagnetic energy as infrared thermal radiation. Due to its function as a susceptor, relatively high chemical purity and high temperature resistance, graphite may be used in the semiconductor industry as a wafer carrier. For example, wafer carriers may be used to grow layers of GaN on wafers to produce blue light-emitting diodes (LED) or High Electron Mobility Transistors (HEMT) by metalorganic vapour-phase epitaxy (MOVPE).

Additionally, graphite may be used as a crucible material in physical vapor transport process for of semiconductor materials, such as SiC. Due to its high temperature stability, graphite crucibles can be used at a wide temperature range. Further, the graphite's high thermal conductivity may allow a more precise control of the temperature of the material disposed within the graphite crucible, allowing the controlled growth of semiconductor crystals for subsequent wafering. In particular, the graphite's high thermal conductivity may allow applying temperature gradients to materials disposed within the crucible with reduced temperature lag.

However, as graphite comprises or substantially consists of carbon it may be prone to chemical attacks. For example, the graphite may be attacked by the hydrogen or ammonia used in the production of semiconductors. Moreover, graphite may still comprise contaminants such as boron which may be undesirably transferred to a semiconductor wafer during high-temperature processes. Indeed, carbon itself could be a contaminant in many semiconductor processes. Further, the surface of graphite may release graphite particles, which can cause damage to the wafer or films grown on the wafer. For example, the surface of graphite may release graphite particles when a wafer disposed therein is moved, e.g. rotated. To increase the chemical resistance, mechanical resistance, and to seal contaminants and particles in the graphite, coatings may be applied to the graphites surface. In particular, metal carbide coatings, such as tantalum carbide coatings, may be used to increase the chemical resistance of the graphite and seal its surface. However, known processes for depositing tantalum carbide on wafer carriers may lead to layers prone to exhibit delamination from the underlying graphite. It is believed that the delamination may occur due to the different thermal expansion coefficients of the tantalum carbide coating and the graphite substrate. Further, some processes may lead to the tantalum carbide completely filling pores of the porous graphite substrate. Due to the different thermal expansion coefficient of the tantalum carbide and the graphite substrate, the tantalum carbide in the pores may expand excessively compared to the surrounding graphite substrate, which may lead to localized destruction of the graphite substrate.

The present disclosure aims to address the aforementioned issues in substrates comprising tantalum carbide coatings.

### SUMMARY

In a first aspect, the present disclosure relates to a gas-phase deposition process for coating a carbonaceous substrate with a tantalum carbide coating, wherein the process comprises a coating step. The coating step comprises placing a carbonaceous substrate into a reaction chamber, heating the reaction chamber to a temperature between about 1100° C. to about 1500° C. for a duration of between about 1 h to about 24 h. The coating step further comprises supplying a process gas to the reaction chamber, wherein the process gas comprises a halide containing species and wherein for at least 15 minutes after the start of the process, the process gas comprises less than 4 at.-% of carbon and less than 10 vol.-% of H₂. Further, the coating step comprises supplying a tantalum containing species to the reaction chamber, or placing a solid comprising tantalum into the reaction chamber. Alternatively, the process comprises placing a solid comprising a tantalum halide into the reaction chamber.

In some embodiments, the solid comprising the tantalum or the tantalum halide may be in the form of a powder.

In some embodiments, the solid comprising the tantalum may comprise tantalum in metallic form.

In some embodiments, the tantalum containing species and the halide containing species may be the same, in particular wherein the process gas may comprise TaCl₅.

In some embodiments, the solid comprising the tantalum halide may comprise the tantalum halide in the form of TaCl₅ and/or other TaClₓ-species.

In some embodiments, the coating step may comprise a first and a second coating step, wherein the first coating step is performed at a first temperature and the second coating step at a second temperature, in particular wherein the first temperature may be lower than the second temperature.

In some embodiments, the first temperature may be between about 1150° C. to about 1250° C. and/or the second temperature may be between about 1250° C. to about 1350° C.

In some embodiments, the coating step may comprise a third coating step, wherein the third coating step may be performed at a third temperature, in particular wherein the third temperature is higher than the first and/or second temperature.

In some embodiments, the third temperature may be at least about 1350° C., more specifically between about 1350° C. to about 1600° C. and in particular between about 1350° C. to about 1450° C.

In some embodiments, the duration of each the first and/or second coating step may be at least about 15 minutes, more specifically between about 30 minutes to about 120 minutes and in particular between about 45 minutes to about 90 minutes.

In some embodiments, the duration of the third coating step may be at least about 60 minutes, more specifically at least about 180 minutes and in particular at least about 300 minutes.

In some embodiments, the process gas in the first coating step may comprise less than 4 at.-%, more specifically less than 1 at.-% and in particular less than 0.1 at.-% carbon, relative to the total number atoms in the process gas.

In some embodiments, the process gas in the first coating step may comprise less than 4 vol.-%, more specifically less than 1 vol.-% and in particular less than 0.1 vol.-% H₂, relative to the total volume of the process gas.

In some embodiments, the process gas in the first coating step may comprise halides, in particular chlorine, to carbon in a maximum ratio of 1:0.05, more specifically 1:0.01 and in particular 1:0.001.

In some embodiments, the process gas in the first coating step may comprise halides, in particular chlorine, to H₂ in a maximum ratio of 1:0.05, more specifically 1:0.01 and in particular 1:0.001.

In some embodiments, the process gas in the second coating step may comprise more than 0.1 at.-%, more specifically more than 1 at.-% and in particular more than 4 at.-% carbon, relative to the total number of atoms in the process gas.

In some embodiments, in the process gas in the third coating step may comprise more than 0.1 at.-%, more specifically more than 1 at.-% and in particular more than 4 at.-% carbon, relative to the total number of atoms in the process gas.

In some embodiments, the halide containing species may be a chloride containing species, more specifically wherein the chloride containing species may be Cl₂ or HCl, and in particular wherein the halide containing species may be HCl.

In some embodiments, the process gas additionally may comprise an inert gas, more specifically nitrogen or argon and in particular argon.

In some embodiments, the pressure in the reaction chamber may be between about 0.001 bar to about 1.1 bar, more specifically between about 0.001 bar to about 0.5 bar and in particular between about 0.1 bar to about 0.2 bar.

In some embodiments, the process additionally may comprise an annealing step following the coating step.

In some embodiments, the annealing step may comprise placing the coated carbonaceous substrate into an annealing chamber, heating the annealing chamber to a temperature between about 900° C. to about 1800° C., more specifically 1200° C. to about 1500° C., for a duration of between about 10 min to about 5 h, and supplying a process gas to the reaction chamber, wherein the process gas may comprise a carbon containing species, more specifically a carbon and hydrogen containing species, and in particular C₂H₄.

In some embodiments, the annealing step may comprise placing the coated carbonaceous substrate into an annealing chamber and heating the reaction chamber to a temperature between about 1900° C. to about 2300° C. for a duration of between about 0.5 h to about 3 h under an inert gas atmosphere.

In a second aspect, the present disclosure relates to a carbonaceous substrate comprising a first tantalum-carbide-coating-layer, wherein the first tantalum-carbide-coating-layer is disposed on an outer surface of the carbonaceous substrate, and wherein the carbonaceous substrate comprises a plurality of pores comprising a TaC-pore-coating, wherein the plurality of pores is not completely filled by the tantalum-carbide-pore-coating.

In some embodiments, the plurality of pores may be disposed less than 182 μm, in particular less than 100 μm from the outer surface.

In some embodiments, the TaC-pore-coating may have a thickness of less than 20 μm, more specifically less than 10 μm and in particular less than 8 μm.

In some embodiments, the TaC-pore-coating at a depth between about 20 μm to about 60 μm may have a thickness between about 0.5 μm to about 8 μm, more specifically between about 0.8 μm to about 3 μm and in particular between about 1 μm to about 2.5 μm.

In some embodiments, the ratio between the thickness of the first tantalum-carbide-coating-layer and the tantalum-carbide-pore-coating at a depth between about 20 μm to about 60 μm may be between about 2:1 to about 30:1, more specifically between about 3:1 to about 20:1 and in particular between about 5:1 to about 15:1.

In some embodiments, the plurality of pores may have a maximum diameter between about 5 μm to about 100 μm, more specifically between about 10 μm to about 50 μm and in particular between 15 μm to about 25 μm.

In some embodiments, at least 50%, more specifically at least 75% and in particular at least 90% of pores, of the plurality of pores, exhibiting a maximum diameter between about 5 μm to about 100 μm, may be not completely filled by the tantalum-carbide-pore-coating.

In some embodiments, a volume of the plurality of pores in the carbonaceous substrate may be between about 1 vol.-% to about 20 vol.-%, more specifically between about 5 vol.-% to about 15 vol.-% and in particular between about 7 vol.-% to about 13 vol.-%.

In some embodiments, the carbonaceous substrate may comprise TaC to a penetration depth of at least 20 μm, more specifically at least 40 μm and in particular at least 60 μm.

In some embodiments, first tantalum-carbide-coating-layer and/or tantalum-carbide-pore-coating may have a ratio of Ta to C of between about 1.3:1 to about 1:1.3, more specifically between about 1.1:1 to about 1:1.1 and in particular between about 1.05:1 to about 1:1.05.

In some embodiments, the first tantalum-carbide-coating-layer may have a thickness between about 0.1 μm to about 40 μm, more between about 5 μm to about 35 μm and in particular between about 10 μm to about 30 μm.

In some embodiments, the first tantalum-carbide-coating-layer may comprise the tantalum carbide in the form of tantalum carbide crystals, wherein each tantalum carbide crystal orientation of the group [111], [200], [220], and exhibits a texture coefficient, TCᵢ, of between about 0.5 to about 1.5 which is calculated from maximum peak intensities of an x-ray diffractogram detected with Cu k-alpha radiation at 1.5406 Å wavelength, according to the following formula:

$$T {C}_{i} = \frac{{I}_{i} / {I}_{i , 0}}{( \frac{1}{n} ) {\sum }_{i = 1}^{n} ( {I}_{i} / {I}_{i , 0} )}$$

wherein Iᵢ is selected correspondingly from the maximum intensities of the crystal orientation, wherein n=5 and wherein
I₁₁₁ is the maximum intensity at 2θ ranging from 33.9° to 35.9°,
I₂₀₀ is the maximum intensity at 2θ ranging from 39.4° to 41.4°,
I₂₂₀ is the maximum intensity at 2θ ranging from 57.6° to 59.6°,
I₃₁₁ is the maximum intensity at 2θ ranging from 69.0° to 71.0°,
I₂₂₂ is the maximum intensity at 2θ ranging from 72.6° to 74.6°,
   and wherein I_{í,0} is the expected intensity of the crystal orientation if the crystal orientation of the tantalum carbide crystals was random.

In some embodiments, the first tantalum-carbide-layer may have a porosity of less than 5 vol.-9%, more specifically less than 1 vol.-% and in particular less than 0.1 vol.-%.

In some embodiments, the first tantalum-carbide-layer may comprise less than 1 at.-%, more specifically less than 0.1 at.-% and in particular less than 0.01 at.-% of impurities.

In some embodiments, the carbonaceous substrate comprises, essentially consists of or consists of graphite.

In some embodiments, the carbonaceous substrate may comprise a second tantalum-carbide-coating-layer, wherein the second tantalum-carbide-coating-layer may be positioned adjacent to the first tantalum-carbide-coating-layer, in particular wherein the first tantalum-carbide-coating-layer may be positioned between the second tantalum-carbide-coating-layer and the outer surface of the carbonaceous substrate.

In a third aspect, the present disclosure relates to a use of a carbonaceous substrate according to any preceding claim as a component for epitaxial growth systems, more specifically GaN or SiC-growth systems, and in particular as a wafer carrier for GaN or SiC-growth systems; or, as a component for physical vapor transport (PVT) systems, more specifically as a component for SiC PVT physical vapor transport systems and in particular as crucibles or hot walls for PVT systems.

### BRIEF DESCRIPTION OF THE FIGURES

FIG. 1 shows the experimental setup for the first and sixth experiment.

FIG. 2 shows the surface morphology of the samples resulting from the first and second experiment.

FIG. 3 shows partially coated pores from the third (c), fourth (b) and fifth (a) Experiments.

FIG. 4 shows the experimental setup for the third and fourth Experiment.

FIG. 5 shows the surface morphology of the samples resulting from the third experiment.

FIG. 6 shows the surface morphology of the samples resulting from the fourth experiment.

FIG. 7 shows the surface morphology of the samples resulting from the fifth experiment.

FIG. 8 shows the surface morphology of the samples resulting from the sixth experiment.

FIG. 9 shows the surface morphology of the samples resulting from the eighth experiment.

FIG. 10 shows the results of x-ray diffractometry of the samples resulting from the seventh experiment.

FIG. 11 shows the penetration depth achieved in the third, fourth and fifth experiment.

FIG. 12 shows the coating thickness relative to the depth of the coating.

FIG. 13 shows the results of x-ray diffractometry of the samples resulting from the sixth experiment.

FIG. 14 shows the results of x-ray diffractometry of the samples resulting from the eighth experiment.

FIG. 15 shows the results of x-ray diffractometry of the samples resulting from the eighth experiment.

FIG. 16 shows the results of x-ray diffractometry of the samples resulting from the ninth experiment.

### DETAILED DESCRIPTION

Hereinafter, a detailed description will be given of the present disclosure. The terms or words used in the description and the aspects of the present disclosure are not to be construed limitedly as only having common-language or dictionary meanings and should, unless specifically defined otherwise in the following description, be interpreted as having their ordinary technical meaning as established in the relevant technical field. The detailed description will refer to specific embodiments to better illustrate the present disclosure, however, it should be understood that the presented disclosure is not limited to these specific embodiments.

### Process

As previously mentioned, it is believed, that delamination of a tantalum carbide coating disposed on a graphite substrate may occur due to the different thermal expansion coefficients of the tantalum carbide coating and the graphite substrate and an insufficient “anchoring” of the tantalum carbide coating into the graphite substrate. Further, some processes may lead to tantalum carbide filling pores of the porous graphite substrate. Due to the different thermal expansion coefficient of the tantalum carbide and the graphite substrate, the tantalum carbide in the pores may expand excessively compared to the surrounding graphite substrate, which may lead to localized destruction of the graphite substrate.

Tantalum carbide naturally comprises tantalum and carbon, and known processes for depositing tantalum carbide on substrates commonly use a tantalum source and carbon source. The tantalum source and carbon source may also be present as a single molecule. It has been surprisingly found, that tantalum carbide coatings may be grown on carbonaceous substrates using tantalum halides at low concentrations of carbon and hydrogen in the process gas. The tantalum halides may be provided into the reaction with the process gas or generated within the reaction chamber. Without wishing to be bound by theory, the tantalum halides may then react with the carbon of the carbonaceous substrate, leading to the formation of tantalum carbide on the carbonaceous substrate, without requiring significant amounts of a carbon source in the process gas. As the tantalum carbide forms directly from carbon provided by the carbonaceous substrate, the anchoring of the tantalum carbide coating to the carbonaceous substrate may be improved.

Further, it has been observed, that the resulting coating may be also present in pores of the carbonaceous substrate, while not filling the pores entirely. Still without wishing to be bound by theory, it is theorized that the growth of the tantalum carbide coating on the carbonaceous coating may be limited by the access of the halide species to the carbon of the carbonaceous substrate. When a tantalum carbide coating is formed in a traditional process from a gas phase comprising both significant amounts of a carbon source and a tantalum source, the tantalum carbide coating may be predominantly formed at the outer surface of a substrate, which may also lead to rapid clogging of any access ways to the pores below the outer surface, leading to poor anchoring of the tantalum carbide coating. Additionally or alternatively, to the pores not being filled, in particular pores close to the surface may be excessively filled, which may subsequently lead to localized destruction as mentioned above.

Further, the presence of significant amounts of dihydrogen, H₂, in the process gas may prevent the formation of TaC. In particular, the presence of H₂ in the process gas may lead to the formation of metallic tantalum on the surface of the carbonaceous substrate, which may require subsequent carbidisation to obtain a tantalum carbide coating. The term “carbidisation” refers to the process of reacting precursors, such as a pure metal and a carbon source, to attain a carbide, in particular a metal carbide, e.g. reacting metallic tantalum with a carbon source to attain tantalum carbide. The metallic tantalum may also form within the pores of the carbonaceous and may fill the pores. During a subsequent carbidisation of the metallic tantalum its volume may increase leading to excessive filling of the pores by tantalum carbide.

The term “outer surface” within this disclosure may refer to a surface, wherein in a direction perpendicular to the surface no other surface of the carbonaceous substrate is disposed. Alternatively or additionally, the term “outer surface” within this disclosure may refer to a surface, wherein at least one reference point on the surface is not enclosed by at least 50% by a wall segment extending away from the bulk. Alternatively or additionally, the term “outer surface” may refer to a surface, wherein at least one reference point on the surface is not surrounded by a wall segment with a height of at least 1 cm extending away from the bulk within a radius of at least 2.5 cm, more specifically at least 3.5 cm and in particular at least 4 cm. For example, the carbonaceous substrate may comprise disc-shaped pockets, wherein the radius of the pockets is 100 mm. The interior of the pockets may still be regarded as an outer surface and not as a recess.

Further, the term “wall segment” refers to a part of a wall, more specifically to a part of a wall with a length of at least 100 μm and in particular to a part of wall with a length of at least 100 μm and a width of at least 10 μm. The width may also be measured along a curved wall segment, along the curved surface.

It has been found, that by providing the tantalum in the form of a tantalum halide and the carbon from the carbonaceous substrate, the formation of the tantalum carbide coating may not predominantly occur at the outer surface, as the growth of the tantalum carbide coating is slowed down as the thickness of the tantalum carbide coating increases. As a result, the tantalum halide may penetrate into the pores and may also form a tantalum-carbide-pore-coating therein. Further, as the formation of the tantalum carbide coating slows with increasing thickness, excessive filling of the pores by the tantalum carbide coating may be prevented, leading to only partially filled pores. Further, while at first the tantalum halide may access the pores, as the tantalum coating grows on the outer surface, the access ways to the pores may become blocked, preventing excessive growth of the tantalum-carbide-pore-coating.

Accordingly, in a first aspect, the present disclosure relates to a gas-phase deposition process for coating a carbonaceous substrate with a tantalum carbide coating, wherein the process comprises a coating step. The coating step comprises placing a carbonaceous substrate into a reaction chamber, heating the reaction chamber to a temperature between about 1100° C. to about 1500° C. for a duration of between about 1 h to about 24 h. The coating step further comprises supplying a process gas to the reaction chamber, wherein the process gas comprises a halide containing species. Further, for at least 15 minutes after the start of the process, the process gas comprises less than 4 atomic (at.)-% of carbon and less than 10 volume (vol.)-% of H₂. The tantalum may be introduced to the reaction chamber by three different ways.

First, the coating step may comprise supplying a tantalum containing species to the reaction chamber. For example, the tantalum containing species and the halide containing species may be the same, in particular wherein the process gas may comprise TaCl₅ and/or other TaClₓ-species. The TaCl₅ and/or other TaClₓ-species may be formed in a separate chamber and then supplied into the reaction. For example, the TaCl₅ and/or other TaClₓ-species may be formed by reacting tantalum metal with a halide, such as HCl or Cl₂ in a separate chamber.

Alternatively or additionally, the coating step may comprise placing a solid comprising tantalum into the reaction chamber. For example, the solid comprising the tantalum may comprise tantalum in metallic form. A halide containing species, such as a hydrogen chloride, HCl, may be supplied to the reaction chamber by the process gas. The halide containing species may then react with the tantalum to form for example gaseous Tantalum (V) chloride, TaCl₅ and/or other TaClₓ-species. The TaCl₅ and/or other TaClₓ-species may then react with carbonaceous substrate to form a tantalum carbide coating and chlorine gas, Cl₂. The other TaClₓ-species may be for example Tantalum (IV) chloride, TaCl₄, or Tantalum (III) chloride, TaCl₃. The solid may be for example a solid plate of metallic tantalum. Alternatively, the solid may be a powder comprising metallic tantalum. The powder may exhibit a higher specific surface area compared to a plate and may therefore react with the halide at an increased rate.

The term “process gas” shall refer to the entirety of gases supplied to the reaction chamber. For example, the reaction chamber may comprise one gas inlet and the term “process gas” may relate to the entire gas stream supplied into the reaction chamber by the one gas inlet. In another example, the reaction chamber may comprise a plurality of gas inlets, wherein the entirety of gases supplied to the reaction chamber via the plurality of gas inlets shall be regarded as the “process gas”. The term “process gas” may also comprise precursor gases formed within the reaction chamber. For example, if the reaction chamber comprises a tantalum halide solid, the term “process gas” may also comprise the gaseous tantalum halide generated from the tantalum halide solid.

Additionally or alternatively, the solid comprising the tantalum halide may comprise the tantalum halide in the form of TaCl₅ and/or other TaClₓ-species. The TaClₓ may evaporate due to the increased temperatures in the reaction chamber and subsequently react with the carbonaceous substrate. The TaClₓ may also be in the form of a powder. The process gas, when placing a tantalum halide solid into the reaction chamber, may also comprise for at least 15 min after the start of the process, less than 4 at.-% of carbon and less than 10 vol.-% of H₂.

Alternatively, when using solid TaClₓ placed into the reaction chamber, the reaction chamber may be sealed and no continuous process gas may be used. For example, when using TaClₓ and a sealed reaction chamber, the reaction chamber may be prefilled with a process gas comprising less than 4 at.-% of carbon and less than 10 vol.-% of H₂ may be used, as both a tantalum containing species and a halide containing species are already present in the reaction chamber.

Alternatively, when using gaseous TaClₓ, for example TaCl₅, the reaction chamber may be filled with the TaClₓ and an inert gas, such as Argon and then sealed. Subsequently, the reaction in the reaction chamber may then be carried out, for example for 1 min to 10 min. After the reaction has been carried out, the reaction chamber may be flushed and the process repeated by again introducing TaClₓ gas and inert gas, sealing the chamber and carrying out the reaction.

It should be noted, that the TaCl₅ may decompose to other TaClₓ species due to the high temperatures in the reaction chamber or process gas. Thus, the process gas may comprise a plurality or any one of TaClₓ species when using TaCl₅. Without wishing to be bound by theory, it is contemplated, that part of the TaClₓ species may temporarily form metallic tantalum on surfaces of the reaction chamber. The metallic tantalum on surfaces of the reaction chamber may subsequently react with react with halides, such as Cl₂, present in the gas within the reaction chamber to again form a TaClₓ species which may then react with carbon from the carbonaceous substrate to form TaC.

In some embodiments, the coating step may comprise a first and a second coating step, wherein the first coating step is performed at a first temperature and the second coating step at a second temperature, in particular wherein the first temperature may be lower than the second temperature. As mentioned above, the reaction of the tantalum halide with the carbonaceous substrate is slowed with increasing thickness of the tantalum carbide coating. Without wishing to be bound by theory, it is believed that a limiting factor may be the diffusion of carbon from the carbonaceous substrate through the tantalum carbide coating to the outer surface where it can react with the tantalum containing species. By increasing the temperature the rate of carbon diffusion through the carbide coating may be increased and thereby increasing the growth rate of the tantalum carbide coating. By at first running the process at a lower first temperature, the tantalum coating may more efficiently penetrate into the pores, while not filling these excessively. Subsequently, when the coating has been anchored to the carbonaceous substrate and the access ways to the pores are partially blocked, the second coating step with a higher second temperature may be performed, to increase the growth rate of the tantalum carbide coating on the outer surface.

As mentioned above, without wishing to be bound by theory, it is believed that an improved tantalum carbide coating may be achieved by having the carbon comprised within the carbonaceous substrate react with a tantalum containing species, as opposed to supplying an additional carbon source in the process gas. Therefore, in some embodiments, the process gas in the first coating step may comprise less than 4 at.-%, more specifically less than 1 at.-% and in particular less than 0.1 at.-% carbon, relative to the total number atoms in the process gas. For example, the process gas in the first coating step may comprise halides, in particular chlorine, to carbon in a maximum ratio of 1:0.05, more specifically 1:0.01 and in particular 1:0.001. The maximum ratio shall refer to the maximum relative amount of carbon. Therefore, a ratio of 1 part chlorine to 1 part carbon shall be regarded as a higher ratio compared to 1 part chlorine to 0.5 parts carbon. Hence, a maximum ratio of chlorine to carbon 1:0.05 relates to all ratios in a range from 1 part chlorine to 0 parts carbon up to 1 part chlorine to 0.05 parts carbon.

In the second coating step, the process gas may also comprise less than 4 at.-%, more specifically less than 1 at.-% and in particular less than 0.1 at.-% carbon, relative to the total number atoms in the process gas. For example, the process gas in the second coating step may comprise halides, in particular chlorine, to carbon in a maximum ratio of 1:0.05, more specifically 1:0.01 and in particular 1:0.001. The increase of the tantalum carbide growth may therefore be induced by an increased temperature.

Alternatively, an additional carbon source may be added to the process gas in the second coating step to increase the growth rate of the tantalum carbide coating on the outer surface. The carbon source may not be able to significantly penetrate into the pores of the carbonaceous substrate in the second coating step, due to access ways being blocked by the tantalum carbide coating formed in the first coating step, thereby preventing excessive filling of the pores. Further, the tantalum carbide coating may have been sufficiently anchored into the pores by the first coating step, reducing the risk of delamination, even if the thickness of the carbide coating on the outer surface is increased in the second coating step. Therefore, in some embodiments, in the process gas in the second coating step may comprise more than 0.1 at.-%, more specifically more than 1 at.-% and in particular more than 4 at.-% carbon, relative to the total number of atoms in the process gas.

In some embodiments, the process gas in the first coating step may comprise less than 4 vol.-%, more specifically less than 1 vol.-% and in particular less than 0.1 vol.-% H₂, relative to the total volume of the process gas. As mentioned above, substantial amounts of H₂ may prevent the formation of a tantalum carbide coating and may result in the formation of a metallic tantalum coating.

In some embodiments, the process gas in the first coating step may comprise halides, in particular chlorine, to H₂ in a maximum ratio of 1:0.05, more specifically 1:0.01 and in particular 1:0.001.

In some embodiments, the first temperature may be between about 1150° C. to about 1250° C. and/or the second temperature may be between about 1250° C. to about 1350° C.

In some embodiments, the duration of each the first and/or second coating step may be at least about 15 minutes, more specifically between about 30 minutes to about 120 minutes and in particular between about 45 minutes to about 90 minutes.

In some embodiments, the coating step may comprise a third coating step, wherein the third coating step may be performed at a third temperature, in particular wherein the third temperature is higher than the first and/or second temperature. In some embodiments, the third temperature may be at least about 1350° C., more specifically between about 1350° C. to about 1600° C. and in particular between about 1350° C. to about 1450° C. The third coating step may be employed to further increase the thickness of the tantalum carbide coating on the outer surface, in particular with a substantially increased growth rate. The third coating step may also be performed directly after first coating step.

It should be noted, that the first, second and third temperature may not be static. The process may be also performed at temperature gradients within the ranges laid out for the first, second and third temperature above. For example, in the first coating step may comprise the temperature increasing from 1150° C. to 1250° C. within one hour.

In some embodiments, the duration of the third coating step may be at least about 60 minutes, more specifically at least about 180 minutes and in particular at least about 300 minutes.

The tantalum carbide coating formed by the first and second coating step may effectively prevent access of the tantalum in the process gas to the carbon of the carbonaceous substrate, hence an additional carbon source in the process gas may be required in the third coating step. Therefore, in some embodiments, in the process gas in the third coating step may comprise more than 0.1 at.-%, more specifically more than 1 at.-% and in particular more than 4 at.-% carbon, relative to the total number of atoms in the process gas.

In some embodiments, the halide containing species may be a chloride containing species, more specifically wherein the chloride containing species may be Cl₂ or HCl, and in particular wherein the halide containing species may be HCl. Cl₂ and HCl may form TaCl₅ and/or other TaClₓ-species when reacting with metallic tantalum, in particular tantalum metal powder. The TaCl₅ and/or other TaClₓ-species may react with the carbonaceous substrate to form the tantalum carbide coating.

In some embodiments, the process gas additionally may comprise an inert gas, more specifically nitrogen or argon and in particular argon.

In some embodiments, the pressure in the reaction chamber may be between about 0.001 bar to about 1.1 bar, more specifically between about 0.001 bar to about 0.5 bar and in particular between about 0.1 bar to about 0.2 bar.

In some embodiments, the process additionally may comprise an annealing step following the coating step.

Tantalum carbide may be present in a stoichiometry deviating from a ratio of tantalum to carbon of 1:1, e.g. pure TaC. For once, the ratio between tantalum and carbon may vary between 1:0.4 to 1:1. Hence, tantalum carbide may be present in the form of TaCₓ, wherein x varies between 0.4 to 1. Additionally, tantalum carbide may also be formed in the form of Ta₂C.

It has been surprisingly found, that coating the carbonaceous substrate using the process parameters of the first coating step may result in a tantalum carbide coating with a ratio of tantalum to carbon close to 1. However, at higher temperatures, e.g. above 1500° C., it was observed that the stoichiometry may change towards a higher proportion of tantalum. In particular, with increasing temperature and increasing coating thickness, the proportion of Ta₂C and metallic tantalum increased. In particular, the proportion of Ta₂C and metallic tantalum was higher at parts of the tantalum carbide coating disposed further away from the carbonaceous substrate. Without wishing to be bound by theory, it is believed that the higher temperature increased the reaction kinetic at the surface of the coating. In particular, the reaction kinetic at the surface may have increased more significantly compared to the diffusion kinetic of the carbon. Further, metallic tantalum may have been disposed on the coating by auto-decomposition of the TaCl₅ and/or other TaClₓ-species at higher temperatures. It was surprisingly found that two annealing methods may be used to increase the proportion of TaC in the tantalum carbide coating and/or to reduce the proportion of Ta₂C and metallic tantalum.

TaC, also referred to as tantalum monocarbide and Ta₂C, also referred to as tantalum hemicarbide, may exhibit different properties. In particular, TaC may exhibit an increased hardness compared to Ta₂C and metallic tantalum. Further, TaC is chemically more stable compared to Ta₂C. For example, in processes for epitaxial growth of SiC, Ta and Ta₂C residuals in the coating may react with the carbonaceous precursor intended for the growth of the SiC, which in turn may change the reaction kinetics of the process leading to poor process results. Further, Ta₂C and Ta may react with other process gas, such as Cl₂ or HCl, which may lead to a degradation of the coating's properties.

In some embodiments, the annealing step may comprise placing the coated carbonaceous substrate into an annealing chamber, heating the annealing chamber to a temperature between about 900° C. to about 1800° C., more specifically 1200° C. to about 1500° C., for a duration of between about 10 min to about 5 h, and supplying a process gas to the reaction chamber, wherein the process gas may comprise a carbon containing species, more specifically a carbon and hydrogen containing species, and In particular C₂H₄. The carbon containing species may provide carbon to the tantalum carbide coating to form TaC from Ta₂C and metallic tantalum. Further, the increased temperatures may also allow a higher rate of diffusion of carbon from the carbonaceous substrate into the tantalum carbide coating.

In another embodiment, the annealing step may comprise placing the coated carbonaceous substrate into an annealing chamber and heating the reaction chamber to a temperature between about 1900° C. to about 2300° C. for a duration of between about 0.5 h to about 3 h under an inert gas atmosphere. The annealing step performed at a temperature 1900° C. to about 2300° C. may be performed without the provision of carbon in the process gas. Without wishing to be bound by theory, it is believed that the temperatures range between about 1900° C. to about 2300° C. may significantly increase the mobility or diffusion rate of the carbon in the tantalum carbide coating. Therefore, carbon may move from the carbonaceous substrate and/or carbon rich parts of the tantalum carbide coating towards carbon poor parts of the tantalum carbide coating.

Further, the tantalum carbide in the tantalum carbide coating may form tantalum carbide grains. The annealing process at temperatures between about 1900° C. to about 2300° C. may lead to an increase of the grain size of the tantalum carbide grains. As a result, the number of grain boundaries and/or absolute length of the grain boundaries in the tantalum carbide coating may be reduced, which may lead to a decreased gas permeability of the tantalum carbide coating. A reduced gas permeability may result in an improved protection of the carbonaceous against chemical attacks.

In some embodiments, the process may be performed under a continuous flow of process gas. A continuous flow process may lead to a higher growth rate of the tantalum carbide layer compared to stationary atmospheres.

In some embodiments, the reaction chamber may be sealed or semi-scaled. In some embodiments, the reaction chamber may be placed in a process cell. The process cell may be scaled. In an unsealed reaction chamber, e.g. in a reaction chamber with continuous flow of process gas, the process gas enters the reaction chamber through an entry and subsequently, after at least partially reacting with the carbonaceous substrate, leaves the reaction chamber. For example, Cl₂ or HCl may enter the reaction chamber via the entry, react with the tantalum metal powder placed in the reaction chamber to form TaCl₅ and/or other TaClₓ-species. The TaCl₅ and/or other TaClₓ-species may then react with the carbonaceous substrate forming the tantalum carbide coating and Cl₂. However, not all of the TaCl₅ and/or other TaClₓ-species may react with the carbonaceous substrate and may be transported out of the reaction chamber, leading to loss of the relatively expensive tantalum. The sealed reaction chamber or sealed process cell may be used by providing HCl or Cl₂ at the start of the reaction to the reaction chamber or the surrounding process cell through gas inlets and subsequently stopping the flow of process gas and closing the gas inlets and outlets. The HCl or Cl₂ may then react with the provided solid tantalum metal, in particular tantalum metal powder to form TaCl₅ and/or other TaClₓ-species, which may again react with the carbonaceous substrate to form the tantalum carbide coating. As the reaction chamber or process cell is sealed, no unreacted TaCl₅ and/or other TaClₓ-species leave the reaction chamber, preventing the loss of tantalum. Still, the growth of the tantalum carbide coating may continue, as the Cl₂ formed when the TaCl₅ and/or other TaClₓ-species react with the carbonaceous substrate, may again react with the solid tantalum metal to again form TaCl₅. As a result, the yield of the tantalum may be increased.

Similarly, the sealed reaction chamber setup or process cell may also be used, when using solid TaCl₅ placed in the reaction chamber as precursor. In this setup, the process gas may be directly formed within the reaction chamber by heating the reaction chamber. By keeping the reaction chamber or process cell sealed, no TaCl₅ and/or other TaClₓ-species may leave the reaction chamber and the TaCl₅ and/or other TaClₓ-species may only react with carbonaceous substrate to form the tantalum carbide coating. As a result, the yield of the tantalum may be increased.

In the semi-scaled reaction chamber, a continuous stream of process gas may flow around the reaction chamber, for example within the process cell. Part of the process gas, in particular the halide containing species, may enter the semi-sealed reaction chamber to react with the solid tantalum metal to form TaClₓ. As the reaction chamber is semi-sealed, the residence time of the halide containing species and the formed TaClₓ may be increased, which may lead to a higher yield of the tantalum, as less tantalum may be lost to the waste stream, compared to the open setup.

The process cell and/or reaction chamber may comprise an agitator configured to stir gas within the process cell and/or reaction chamber. For example the process cell and/or reaction chamber may comprise a fan. The agitator may increase the growth rate of the tantalum carbide coating for example by reducing dead zones, which may for example form in corners of the process cell and/or reaction chamber. Further, the rate of gas exchange at the surface of the carbonaceous surface may be increased, which may also increase the reaction rate. As mentioned above, at the surface of the carbonaceous substrate, tantalum halides, such as TaClₓ, may react with the carbonaceous substrate to form TaC and halides, such as Cl₂. For example, the agitator may increase the rate at which the Cl₂ is replaced by TaClₓ at the carbonaceous substrate's surface. The TaClₓ may then react with the carbonaceous substrate again. Further, due to the agitator the Cl₂ may more quickly get into contact with the solid tantalum metal, if present, to again form TaClₓ.

### Substrate

In a second aspect, the present disclosure relates to a carbonaceous substrate comprising a first tantalum-carbide-coating-layer, wherein the first tantalum-carbide-coating-layer is disposed on an outer surface of the carbonaceous substrate, and wherein the carbonaceous substrate comprises a plurality of pores comprising a tantalum-carbide-pore-coating, wherein the plurality of pores is not completely filled by the tantalum-carbide-pore-coating.

In some embodiments, the plurality of pores may be disposed less than 182 μm, in particular less than 100 μm from the outer surface. It should be noted that pores may be present in portions of the carbonaceous further removed from the outer surface, than 182 μm or 100 μm. However, pores further from the outer surface may not be relevant for the anchoring of the first tantalum-carbide-coating-layer. Further, pores disposed further away from the outer surface may not come into significant contact with the tantalum halide species and may therefore not exhibit a significant tantalum-carbide-pore-coating after the coating process.

In some embodiments, the tantalum-carbide-pore-coating may have a thickness of less than 20 μm, more specifically less than 10 μm and in particular less than 8 μm.

In some embodiments, the tantalum-carbide-pore-coating at a depth between about 20 μm to about 60 μm may have a thickness between about 0.5 μm to about 8 μm, more specifically between about 0.8 μm to about 3 μm and in particular between about 1 μm to about 2.5 μm. As mentioned above, an excessive tantalum-carbide-pore-coating thickness may lead to localized destruction of the carbonaceous substrate at increased temperatures, due to the tantalum carbide expanding. However, the provision of tantalum-carbide-pore coating with a minimal thickness may improve the anchoring of the first tantalum-carbide-coating-layer to the carbonaceous substrate and increase the resistance of the pores to chemical attacks.

In some embodiments, the ratio between the thickness of the first tantalum-carbide-coating-layer and the tantalum-carbide-pore-coating at a depth between about 20 μm to about 60 μm may be between about 2:1 to about 30:1, more specifically between about 3:1 to about 20:1 and in particular between about 5:1 to about 15:1. The term “depth” is well-known and i.a. (inter alia) attributed its common meaning in the art. Additionally or alternatively, the term “depth” may refer to a direction extending into the bulk of a material in a direction perpendicular to that material's outer surface.

The thickness of the tantalum-carbide-pore-coating at a depth of between about 20 μm to about 60 μm may be measured by the following protocol:
a) An SEM-overview-image showing the substrate depth of between about 20 μm to about 60 μm is created. The width of the created SEM-overview-image is chosen such that at least 30 pores with a maximum diameter of at least 5 μm are present. The SEM-overview-image may be formed of multiple SEM-images juxtaposed next to one another,
b) All pores with a maximum diameter of at least 5 μm in the SEM-overview-image are identified as a subset of pores,
c) The thickness of the tantalum-carbide-pore-coating perpendicular to the underlying carbonaceous substrate is determined at 5 positions distributed equidistantly along the circumference of each pore of the subset of pores,
d) The thickness of the tantalum-carbide-pore-coating is calculated by averaging the determined thicknesses of the tantalum-carbide-pore coating in step c) at all 5 positions of all pores of the subset of pores.

It has been found that the process described above may allow coating pores of smaller maximum diameters compared to known processes. In some embodiments, the plurality of pores may have a maximum diameter between about 5 μm to about 100 μm, more specifically between about 10 μm to about 50 μm and in particular between 15 μm to about 25 μm. Pores in the carbonaceous substrate may also exhibit smaller or greater diameters, however, these shall not be regarded as belonging to the plurality of pores defined herein. However, the volume of the plurality of pores may make up at least 50%, more specifically at least 75% and in particular at least 90% of the volume of the total volume of pores disposed less than 182 μm, in particular less than 100 μm from the outer surface. The volume of the tantalum-carbide-pore-coating shall be regarded as part of the pore volume of the plurality of pores. Smaller pores, given the same proportion of pore volume, may improve the anchoring of the first tantalum-carbide-coating by providing more anchoring sites, compared to bigger pores. However, if there is a high degree of pores smaller than 5 μm these may become excessively filled by the tantalum-carbide-pore-coating, which may lead to the aforementioned partial destruction of the carbonaceous substrate. As previously mentioned, the process according to the first aspect may allow coating pores of a smaller maximum diameter with tantalum-carbide-pore-coating compared to known processes.

In some embodiments, at least 50%, more specifically at least 75% and in particular at least 90% of pores, of the plurality of pores, exhibiting a maximum diameter between about 5 μm to about 100 μm, may be not completely filled by tantalum carbide, in particular at a depth between about 20 μm to about 60 μm. Some pores of the plurality of pores, in particular pores disclosed closely to the outer surface, may be completely filled by the tantalum-carbide-pore-coating.

In some embodiments, a volume of the plurality of pores in the carbonaceous substrate may be between about 1 vol.-% to about 20 vol.-%, more specifically between about 5 vol.-% to about 15 vol.-% and in particular between about 7 vol.-% to about 13 vol.-%. A substrate with a higher porosity may improve the anchoring of the first tantalum-carbide-coating-layer.

However, carbonaceous substrates with a lower porosity may exhibit improved mechanic properties. Additionally, carbonaceous substrates with a lower volume of pores, in particular isostatic graphite, may exhibit a smaller pore size, which may improve anchoring as outlined above. However, it is possible to create carbonaceous substrates, in particular isostatic graphite, with a higher volume of the plurality of pores. In some embodiments, the carbonaceous substrate may therefore comprise between about 7 vol.-% to about 20 vol.-% of the plurality of pores, wherein at least 50%, more specifically at least 75% and in particular at least 90% of the pores of the plurality of pores have a maximum diameter between about 5 μm to about 100 μm.

In some embodiments, the carbonaceous substrate may comprise TaC to a penetration depth of at least 20 μm, more specifically at least 40 μm and in particular at least 60 μm. As previously mentioned, the process described above, may allow the tantalum halide species to penetrate deeper into the carbonaceous substrate, which may improve the anchoring of the first tantalum-carbide-coating-layer and chemical resistance of the carbonaceous substrate.

In some embodiments, first tantalum-carbide-coating-layer and/or tantalum-carbide-pore-coating may have a ratio of Ta to C of between about 1.3:1 to about 1:1.3, more specifically between about 1.1:1 to about 1:1.1 and in particular between about 1.05:1 to about 1:1.05. As mentioned above, it has been surprisingly found, that coating the carbonaceous substrate using the process parameters of the first coating step may result in a tantalum carbide coating with a ratio of tantalum to carbide close to 1. Further, a tantalum coating comprising predominantly TaC, as opposed to Ta₂C or metallic tantalum may exhibit improved properties, such as increased mechanical hardness and chemical resistance, as mentioned above. A coating comprising more carbon compared to tantalum may for example comprise domains of crystalline graphite, which may also exhibit reduced mechanical properties and chemical resistance.

In some embodiments, the first tantalum-carbide-coating-layer may have a thickness between about 0.1 μm to about 40 μm, more between about 5 μm to about 35 μm and in particular between about 10 μm to about 30 μm. The thickness of the first tantalum-carbide-coating-layer may be determined perpendicular to the outer surface.

Tantalum carbide coating layers are typically present in the form of crystals. The tantalum carbide layers produced by the process according to the first aspect may exhibit a characteristic distribution of the tantalum carbide crystals measured by x-ray diffractometry. In particular, the process according to the first aspect, may result in a tantalum carbide layer comprising tantalum carbide crystals, wherein the tantalum carbide crystals do not exhibit a preferred orientation, thus wherein the orientation of tantalum carbide crystals is predominantly random. Hence, in some embodiments, the first tantalum-carbide-coating-layer may comprise the tantalum carbide in the form of tantalum carbide crystals, wherein each tantalum carbide crystal orientation of the group [111], [200], [220], and exhibits a texture coefficient, TCᵢ, of between about 0.5 to about 1.5 which is calculated from maximum peak intensities of an x-ray diffractogram detected with Cu k-alpha radiation at 1.5406 Å wavelength, according to the following formula:

$$T {C}_{i} = \frac{{I}_{i} / {I}_{i , 0}}{( \frac{1}{n} ) {\sum }_{i = 1}^{n} ( {I}_{i} / {I}_{i , 0} )}$$

wherein Iᵢ is selected correspondingly from the maximum intensities of the crystal orientation, wherein n=5 and wherein
I₁₁₁ is the maximum intensity at 2θ ranging from 33.9° to 35.9°,
I₂₀₀ is the maximum intensity at 2θ ranging from 39.4° to 41.4°,
I₂₂₀ is the maximum intensity at 2θ ranging from 57.6° to 59.6°,
I₃₁₁ is the maximum intensity at 2θ ranging from 69.0° to 71.0°,
I₂₂₂ is the maximum intensity at 2θ ranging from 72.6° to 74.6°,
   and wherein I_{í,0} is the expected intensity of the crystal orientation if the crystal orientation of the tantalum carbide crystals was random.

Tantalum carbide coatings exhibiting a substantially random crystal orientation may exhibit a higher chemical resistance.

Tantalum carbide coatings comprising a substantially random crystal orientations may for example also be produced by sintering tantalum carbide particles on the surface of a substrate. However, tantalum carbide coatings formed by sintering may be porous. To reduce the porosity sintering aids may be mixed with tantalum carbide particles. However, the sintering aids may introduce unwanted impurities into the tantalum carbide coating.

In some embodiments, the first tantalum-carbide-layer may have a porosity of less than 5 vol.-%, more specifically less than 1 vol.-% and in particular less than 0.1 vol.-%.

In some embodiments, the first tantalum-carbide-layer may comprise less than 1 at.-%, more specifically less than 0.1 at.-% and in particular less than 0.01 at.-% of impurities. The term “impurities” within this disclosure shall refer to elements other than tantalum and carbon.

In some embodiments, the distribution of the tantalum carbide crystal orientations may exhibit a texture coefficient between about 0.35 to about 0.6, more specifically between about 0.35 to about 0.55 and in particular between about 0.4 to about 0.52.

In some embodiments, the carbonaceous substrate comprises, essentially consists of or consists of graphite, in particular isostatic graphite. As mentioned above, graphite may exhibit high temperature resistance, a high melting point, a high thermal conductivity and low coefficient of thermal expansion and may therefore be used in numerous high-temperature processes. Further, graphite may be used as a susceptor and may exhibit a relatively high chemical purity. Further, graphite consists predominantly of carbon and may therefore provide the carbon for the formation of the first tantalum-carbide-coating-layer and tantalum-carbide-pore-coating. In particular, isostatic graphite may possess improved mechanical properties compared to other graphite types, such as extruded or vibromolded graphite. Further, the isostatic graphite may have pores of an average smaller maximum pore diameter. As mentioned above, the process described herein may allow coating pores of smaller maximum pore diameter, allowing anchoring of a first tantalum-carbide-coating-layer into isostatic graphite.

The term “graphite” is well known and attributed its common meaning in the art. More specifically, the term “graphite” may refer to a material comprising crystalline carbon in a hexagonal structure. Alternatively or additionally, the term “graphite” may refer to a material comprising at least about 60 at.-%, more specifically at least about 80 at.-% and in particular at least about 83 at.-% crystalline carbon in a hexagonal structure. Alternatively or additionally, the term “graphite” may refer to a material with a graphitization degree of at least about 46 at.-%, more specifically 69 at.-%, even more specifically at least about 80 at.-% and in particular at least about 83 at.-%.

The graphitization degree of carbonaceous substrate may be measured by XRD. The crystalline carbon in the graphite forms a plurality of honeycomb lattice. XRD may be used to measure the interplane distance door between the plurality of lattices. Hence, the term “graphite” may additionally or alternatively refer to a carbonaceous material, wherein the carbonaceous material has a an interplane distance between about 0.3400 to about 0.3354, more specifically 0.3381 to about 0.3354, even more specifically between about 0.3371 to about 0.3354 and in particular between about 0.3369 to about 0.3354. To perform the XRD measurement on a graphite substrate according to the present disclosure, the tantalum-carbide-coating-layer and tantalum-carbide-pore-coating must be removed and only the underlying carbonaceous material shall be used for the measurement.

The interplane distance may also be used to calculate the graphitization degree by the following formula:

$$Graphitization Degree = \frac{0.3440 - {d}_{00 l}}{0.3440 - 0.3354}$$

The 0.3340 corresponds to the interplane distance of turbostratic graphite and the 0.3354 corresponds to the interplane distance in a perfect graphite crystal.

In some embodiments, the carbonaceous substrate may exhibit a graphitization degree of between about 46 at.-% to about 83 at.-%, more specifically between about 46 at.-% to about 69 at.-%. The coefficient of thermal expansion of graphite with a lower graphitization may be closer to that of tantalum carbide, compared to a graphite with a higher degree of graphitization. As a result, a graphite with a lower degree of graphitization may result in a higher thermal stability of the carbonaceous substrate.

In some embodiments, the carbonaceous substrate may comprise carbon fiber reinforced carbon, CFRC, more specifically wherein the carbonaceous substrate may comprise at least about 90 wt.-% CFRC and in particular wherein the carbonaceous substrate may comprise at least about 99 wt.-% CFRC, relative to the total weight of the carbonaceous substrate. CFRC may exhibit improved mechanical properties compared to other carbonaceous substrates. Further, CRFC also consists predominantly of carbon and may therefore provide the carbon for the formation of the first tantalum-carbide-coating-layer and the tantalum-carbide-pore-coating. The term “CFRC” is well known and attributed its common meaning in the art. More specifically, the term “CFRC” may refer to a composite material comprising carbon fibers in a matrix of graphite. In particular, the term “CFRC” may refer to a composite material consisting of carbon fibers in a matrix of graphite.

In some embodiments, the carbonaceous substrate may comprise a second tantalum-carbide-coating-layer, wherein the second tantalum-carbide-coating-layer may be positioned adjacent to the first tantalum-carbide-coating-layer, in particular wherein the first tantalum-carbide-coating-layer may be positioned between the second tantalum-carbide-coating-layer and the outer surface of the carbonaceous substrate. The second tantalum-carbide-coating-layer may be disposed on the first tantalum-carbide-coating-layer. For example, the first tantalum-carbide-coating-layer may be formed by the first coating step. Subsequently, the second or third coating step may be used to deposit the second tantalum-carbide-coating-layer upon the first tantalum-carbide-coating-layer. The first tantalum-carbide-coating-layer may be formed on the carbonaceous substrate by the first coating step to achieve an improved anchoring and only partial filling of the plurality of pores. However, it may be preferable to have a tantalum carbide layer of greater thickness disposed on the outer surface of the carbonaceous substrate, than is provided by the first tantalum-carbide-coating-layer, for example to improve the mechanical properties and chemical resistance of the carbonaceous substrate. However, as mentioned above, the growth of the first tantalum-carbide-coating-layer by the first coating step may be exceedingly slowed down with increasing thickness of the first tantalum-carbide-coating-layer. As a result, the second or third coating step at increased temperatures and/or with an additional carbon source in the process gas may be used to increase the overall thickness of the tantalum carbide coating provided on the carbonaceous substrate. The properties of the second tantalum-carbide-coating-layer may differ from those of the first tantalum-carbide-coating-layer. For example, the second tantalum-carbide-coating-layer may exhibit a different stoichiometry of tantalum and carbon and/or a different tantalum carbide crystal orientation. However, the second tantalum-carbide-coating-layer may also grow epitaxially on the first tantalum-carbide-coating-layer or align to the first tantalum-carbide-coating-layer during the annealing step and therefore exhibit the tantalum carbide crystal orientation described above. Additionally, as mentioned above, the annealing step may also shift the stoichiometry of tantalum and carbon towards carbon, such that the second tantalum-carbide-coating-layer may subsequently also exhibit a stoichiometric ratio of tantalum to carbon close to 1.

### Use

In a third aspect, the present disclosure relates to a use of a carbonaceous substrate according to any preceding claim as a component for epitaxial growth systems, more specifically GaN or SiC-growth systems, and in particular as a wafer carrier for GaN or SiC-growth systems; or, as a component for physical vapor transport systems (PVT), more specifically as a component for SiC PVT systems for SiC single-crystal growth and in particular as crucibles or hot walls for PVT systems.

In a fourth aspect, the present disclosure relates to a process for annealing a carbonaceous substrate comprising a tantalum carbide coating. The annealing step according to the fourth aspect comprises placing the coated carbonaceous substrate into an annealing chamber, heating the annealing chamber to a temperature between about 900° C. to about 1800° C. for a duration of between about 10 min to about 5 h and supplying a process gas to the reaction chamber, wherein the process gas comprises a carbon containing species, more specifically a carbon and hydrogen containing species, and in particular C₂H₄.

In a fifth aspect, the present disclosure relates to a process for annealing a carbonaceous substrate comprising a tantalum carbide coating. The annealing step according to the fifth aspect comprises placing the coated carbonaceous substrate into an annealing chamber and heating the reaction chamber to a temperature between about 1900° C. to about 2300° C. for a duration of between about 0.5 h to about 3 h under an inert gas atmosphere.

### EXPERIMENTAL SECTION

### Sample Preparation

For each of the following examples graphite substrates were used. The used graphite was isostatic graphite grade R6810, purchasable from the company SGL Carbon GmbH, Germany. The cuboid graphite substrates had the dimensions 10 cm×6 cm×0.15 cm.

### Experimental Setup

The following examples were all performed in a lab-scale low-pressure CVD reactor. The CVD reactor comprised a cell with a gas inlet and outlet disposed opposite one another. The reaction chamber itself was placed into the cell and comprised a an inductively heated graphite susceptor with the dimensions 20 cm×8 cm×2 cm. Time series test were conducted by placing four graphite samples in the reaction chamber and removing one sample after one quarter of the total process duration had elapsed.

### First Experiment

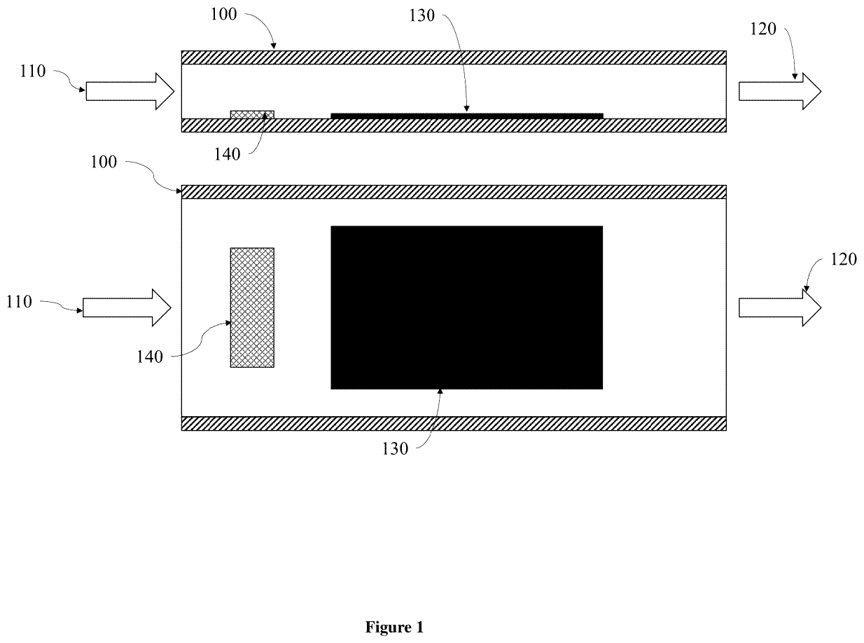

A setup of the first experiment can be viewed in FIG. 1. In the first experiment, tantalum metal powder (140) was loaded into the reaction chamber (100). Next to the metal powder (140) the graphite substrate (130) was placed, wherein the graphite substrate (130) was placed in the downstream direction of the metal powder (140). The cell and reaction chamber (100) were then evacuated and the susceptor was heated under a gas stream flow (110) of argon, Ar, as carrier gas until a temperature of 1200° C. was reached. When the temperature of 1200° C. was reached HCl was added to the gas stream flow (110) to form the process gas. The flow rate of the Ar was 1000 sccm and the flow rate of HCl was 100 sccm. The reaction chamber was not sealed; therefore the process gas was able to leave the reaction chamber (100) as waste gas (120). The pressure in the reaction chamber (100) was held at 150 mbar and the reaction was carried out for 3 h.

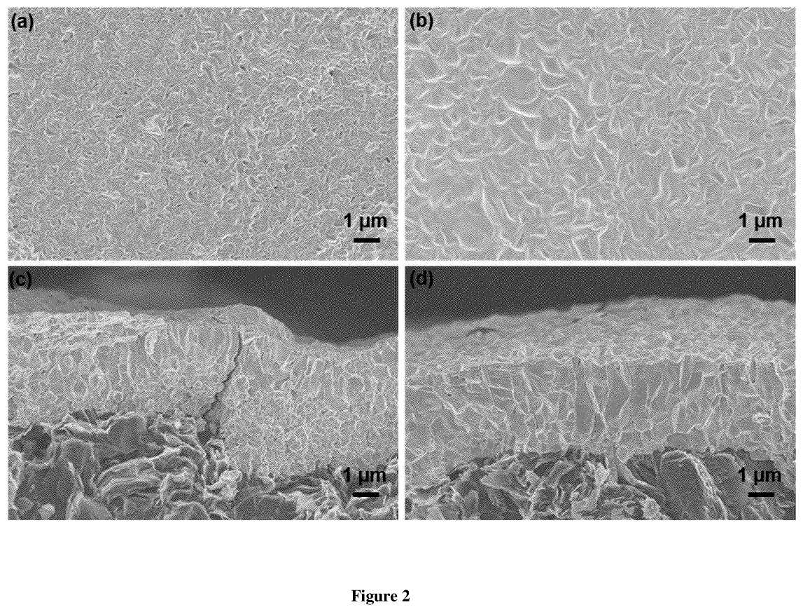

The thickness of the resulting tantalum carbide coating was 3.7 μm. As shown in FIGS. 2a and 2c, the resulting coating was dense and smooth at the surface.

The result of the X-ray diffractometry of the coated samples are shown in Table 1.

TABLE 1
TC of crystalline plane measured by an X-ray diffractogram

| Crystalline plane | TC |
|---|---|
| (111) | 1.0 |
| (200) | 1.2 |
| (220) | 1.1 |
| (311) | 0.9 |
| (222) | 0.8 |

As can be derived from Table 2, the tantalum-carbide-coating-layer did not show a significantly preferred crystalline orientation.

### Second Experiment

The setup of the second experiment corresponded to the setup of the first Experiment. In the second experiment the temperature was increased to 1300° C., all other parameters remained unchanged.

The thickness of the resulting tantalum carbide coating was 3.3 μm. It was found that using the higher temperature led to the formation of a crust on the tantalum metal powder, which may have decreased the growth rate of the tantalum carbide coating compared to the lower temperature. Hence, when using a tantalum metal powder a lower temperature may be used for the coating process. As shown in FIGS. 2b and 2d, the resulting coating was dense and smooth at the surface. The resulting tantalum carbide crystals in the second experiment are greater in size compared to those in the first experiment.

The result of the X-ray diffractometry of the coated samples are shown in Table 2.

TABLE 2
TC of crystalline plane measured by an X-ray diffractogram

| Crystalline plane | TC |
|---|---|
| (111) | 0.9 |
| (200) | 1.3 |
| (220) | 1.0 |
| (311) | 1.0 |
| (222) | 0.8 |

As can be derived from Table 2, the tantalum-carbide-coating-layer did not show a significantly preferred crystalline orientation.

### Third Experiment

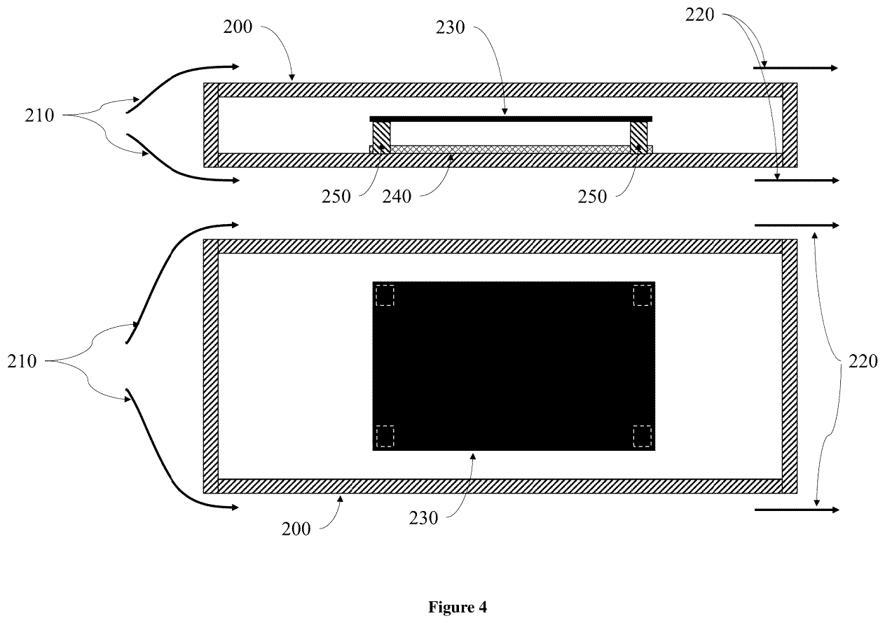

In the third experiment a semi-sealed reaction chamber was used. The setup of the third experiment can be viewed in FIG. 4. Again, a tantalum metal powder (240) was loaded into the reaction chamber (200). The graphite substrate (230) was placed above the tantalum metal powder (240) and was supported by four support pieces of graphite felt (250). The cell and reaction chamber (200) were evacuated and then heated to a temperature of 1300° C. under a stream of 1000 sccm Ar at 150 mbar pressure. Upon reaching a temperature of 1300° C. a flow rate of the Ar 1000 sccm and HCl 100 sccm at a pressure of 150 mbar was applied as process gas. The reaction was carried out for 3 h. As shown in FIG. 4 the process gas (210) streamed around the semi-sealed reaction chamber within the cell. However, parts of the gas stream (210) could enter the semi-sealed reaction chamber, before leaving as waste gas (220), to react with the tantalum metal powder to form TaClₓ-species.

It is believed, that in this setup, after the TaClₓ has reacted with the graphite, the resulting Cl₂ has reacted again with tantalum metal powder to again form TaClₓ.

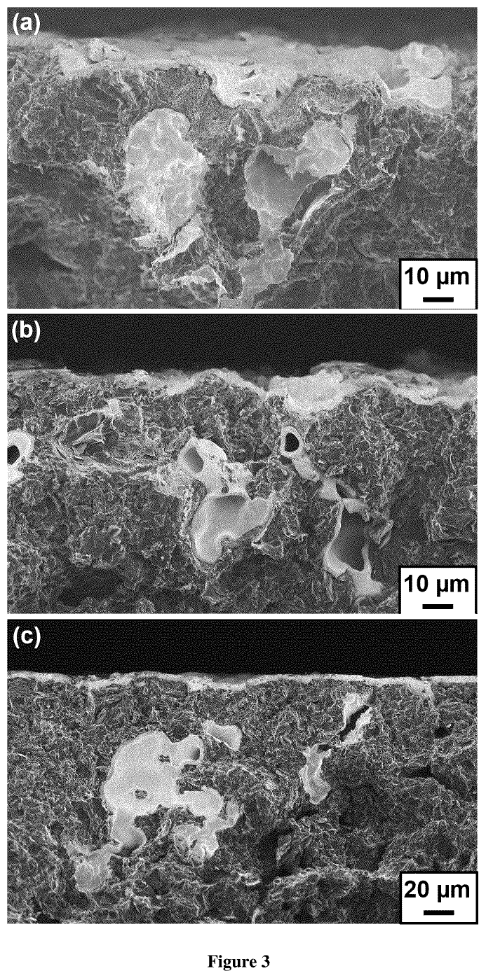

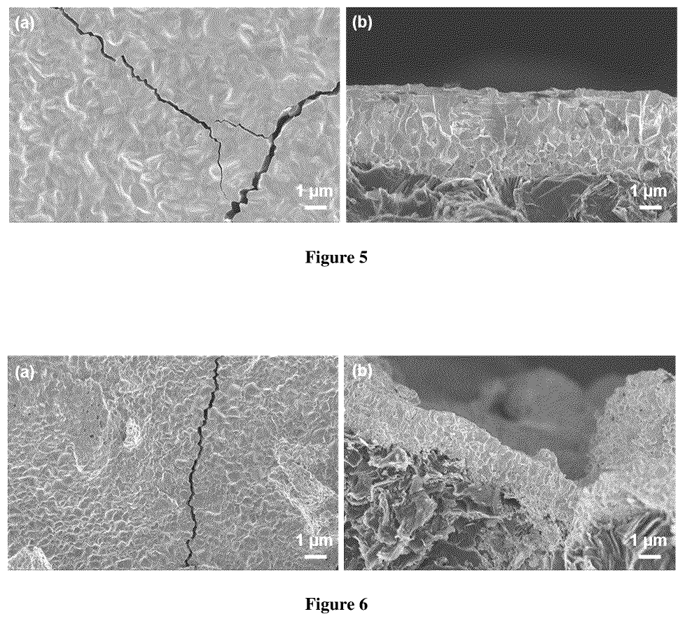

The thickness of the resulting tantalum carbide coating was 3.7 μm. The coating was dense and smooth at the surface as shown in FIG. 5b. However, cracks were observed as shown in FIG. 5a. The pores were only partially coated as can be seen in FIG. 3c.

The result of the X-ray diffractometry of the coated samples are shown in Table 3.

TABLE 3
TC of crystalline plane measured by an X-ray diffractogram

| Crystalline plane | TC |
|---|---|
| (111) | 0.9 |
| (200) | 1.2 |
| (220) | 1.3 |
| (311) | 0.9 |
| (222) | 0.7 |

As can be derived from Table 3, the tantalum-carbide-coating-layer did not show a significantly preferred crystalline orientation.

### Fourth Experiment

In the fourth experiment, a sealed process cell was used with a semi-sealed reaction chamber. The test setup corresponded to that of the third experiment and can hence be viewed in FIG. 4 Again, a tantalum metal powder was loaded into the reaction chamber and the graphite substrate was placed above the tantalum metal powder supported by four support pieces of graphite felt. The reaction chamber and process cell were evacuated and subsequently, the process cell was filled with Ar at a flow rate of 1000 sccm and HCl at a flow rate 100 sccm until a pressure of 150 mbar was reached. The gas inlet and outlet of the process cell were then closed to have a sealed process cell. The process gas, including the HCl, again could enter the semi-sealed reaction chamber. Subsequently, the reaction chamber was heated to a temperature of 1200° C. for 3 hours to perform the coating step.

The thickness of the resulting tantalum carbide coating was 1.5 μm. The coating was dense as shown in FIG. 6b. However, cracks were observed as shown in FIG. 6a. The pores were only partially coated as can be seen in FIG. 3b.

The result of the X-ray diffractometry of the coated samples are shown in Table 4.

TABLE 4
TC of crystalline plane measured by an X-ray diffractogram

| Crystalline plane | TC |
|---|---|
| (111) | 1.1 |
| (200) | 1.3 |
| (220) | 1.0 |
| (311) | 0.9 |
| (222) | 0.8 |

As can be derived from Table 4, the tantalum-carbide-coating-layer did not show a significantly preferred crystalline orientation.

### Fifth Experiment

In the fifth experiment, a sealed process cell was used with a semi-sealed reaction chamber. The test setup was the same as in fourth experiment. However, in the fifth experiment a mixture of tantalum metal powder and TaCl₅ was loaded into the reaction chamber and the graphite substrate was placed above the powder mixture supported by four support pieces of graphite felt. The reaction chamber and process cell were evacuated and subsequently, the process cell was filled with only Ar at a flow rate of 1000 sccm until a pressure of 150 mbar was reached. No HCl or other gaseous halide source was added. The gas inlet and outlet of the process cell were then closed to have a sealed process cell. Subsequently, the reaction chamber was heated to a temperature of 1300° C. for 3 hours to perform the coating step.

Both the TaCl₅ powder as well as the tantalum metal powder had reacted with the graphite substrate during the process. It is believed, that the TaCl₅ powder evaporated and reacted with the graphite substrate to form tantalum carbide, while releasing Cl₂, which subsequently reacted with the tantalum metal powder to again form TaClₓ.

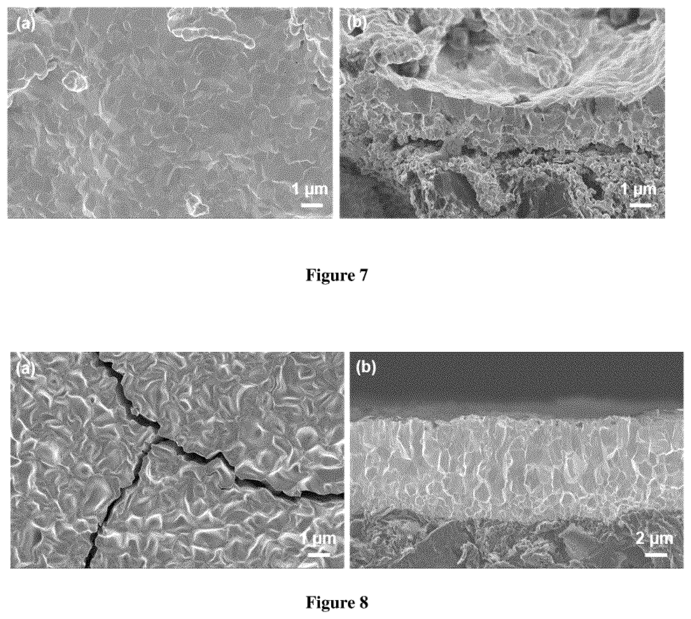

The thickness of the resulting tantalum carbide coating was 2.2 μm. The coating was dense, as shown in FIGS. 7a and 7b. The pores were only partially coated as can be seen in FIG. 3a.

The result of the X-ray diffractometry of the coated samples are shown in Table 5.

TABLE 5
TC of crystalline plane measured by an X-ray diffractogram

| Crystalline plane | TC |
|---|---|
| (111) | 0.8 |
| (200) | 1.2 |
| (220) | 1.0 |
| (311) | 1.1 |
| (222) | 0.9 |

As can be derived from Table 5, the tantalum-carbide-coating-layer did not show a significantly preferred crystalline orientation.

### Sixth Experiment

The setup of the sixth experiment was the same as for the first experiment. Therefore, the setup of the sixth experiment can be viewed in FIG. 1. As opposed to the first experiment, no tantalum metal powder was loaded into the reaction chamber. The cell and reaction chamber were evacuated and the susceptor was heated under a gas stream flow of argon, Ar, as carrier gas until a temperature of 1300° C. was reached. When the temperature of 1300° C. was reached TaCl₅ was added to the gas stream flow to form the process gas. The flow rate of the Ar was 1000 sccm. The flow rate of the TaCl₅ was approximately 5 sccm. The TaCl₅ was generated in an external evaporator. The reaction chamber was not sealed, therefore the process gas was able to leave the reaction chamber as waste gas. The pressure in the chamber was held at 150 mbar and the reaction was carried out for 12 h.

The thickness of the resulting tantalum carbide coating was 8.8 μm. The coating was dense and smooth at the surface, as shown in FIG. 8b. However, as shown in FIG. 8a the coating also showed cracks.

The result of the X-ray diffractometry of the coated samples are shown in Table 6.

TABLE 6
TC of crystalline plane measured by an X-ray diffractogram

| Crystalline plane | TC |
|---|---|
| (111) | 0.8 |
| (200) | 1.6 |
| (220) | 1.2 |
| (311) | 0.9 |
| (222) | 0.6 |

As can be derived from Table 6, the tantalum-carbide-coating-layer did not show a significantly preferred orientation.

The process lead to a TaC-coating of high purity as shown in FIG. 13.

### Seventh Experiment

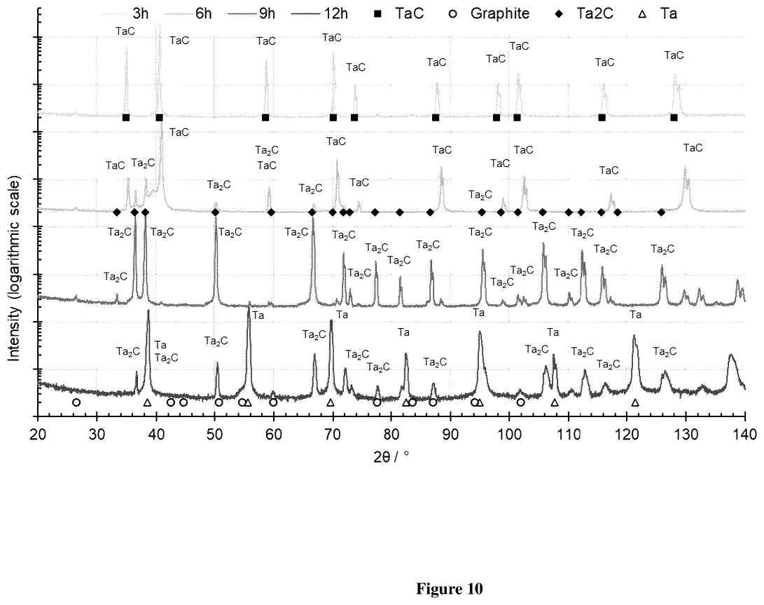

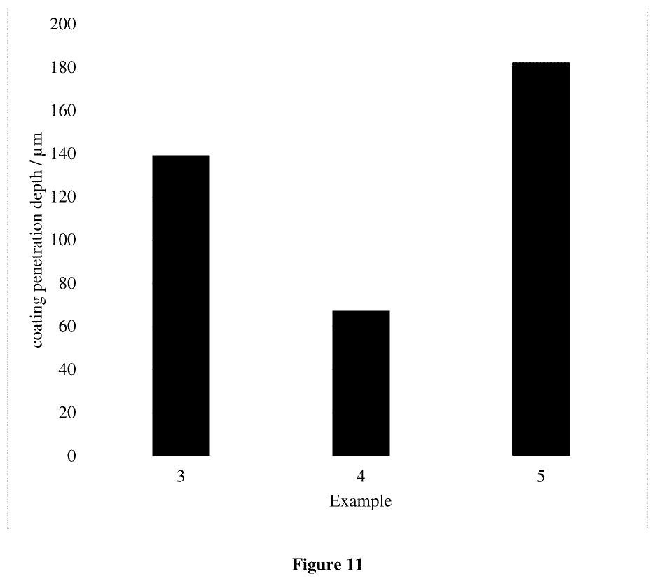

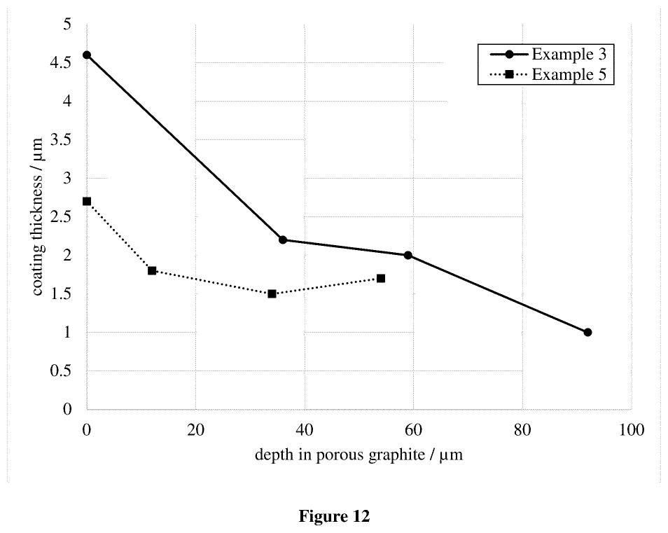

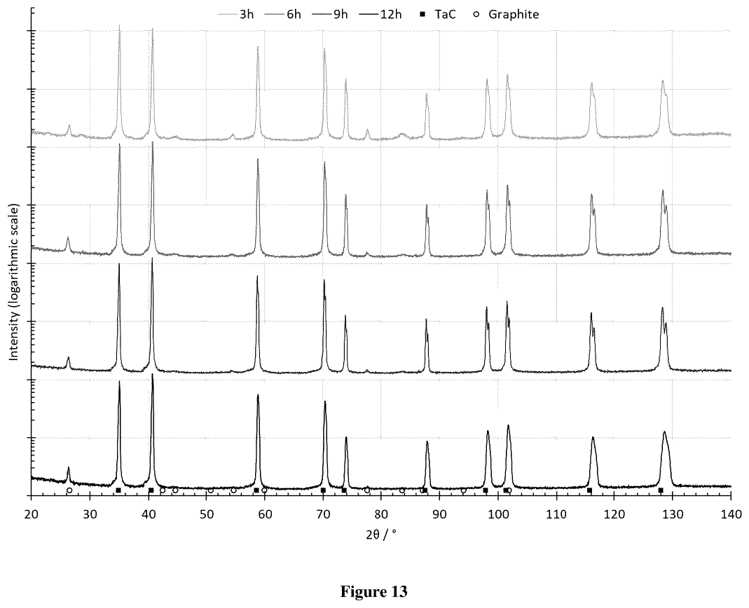

In the seventh experiment, the same setup as for the sixth experiment was used. However, the temperature was set to 1500° C. Four samples were placed into the reaction chamber and every 3 hours one samples was removed and analyzed. The thickness of the coating after 12 hours of the coating process was 35 μm. However, the stoichiometry of the coating changed from TaC towards Ta₂C and Ta with increasing coating thickness. The change of proportion of Ta₂C, Ta and TaC was determined by performing x-ray diffractometry on the four samples. The results of the x-ray diffractometry are shown in FIG. 10.

### Eighth Experiment

In the eighth experiment the effect of annealing at 2100° C. without a carbon source was tested. The samples of the experiments three, four, six and seven were annealed in an annealing oven for 1 hour at a temperature of 2100° C. in an Ar atmosphere.

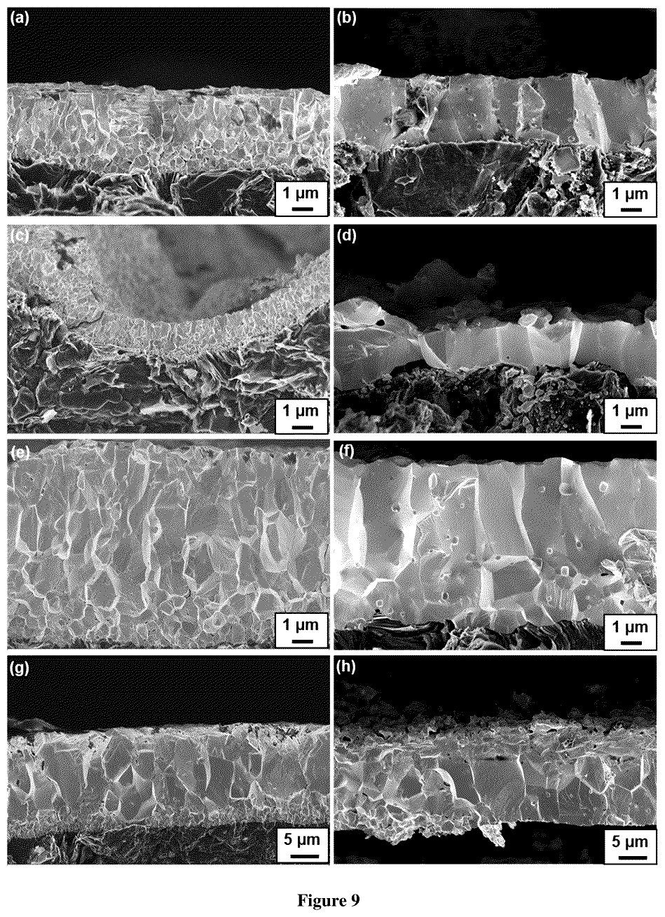

FIGS. 9 a, c, e, g show the samples before annealing and FIGS. 9 b, d, f, h show the samples after annealing. FIG. 9a, 9b show a sample of the third experiment which was coated for 3 h before and after annealing at 2100° C. FIG. 9c, 9d show a sample of the fourth experiment which was coated for 3 h before and after annealing at 2100° C. FIG. 9e, 9f show a sample of the sixth experiment which was coated for 12 h before and after annealing at 2100° C. FIG. 9g, 9h show a sample of the seventh experiment which was coated for 6 hours before and after annealing at 2100° C. As can be derived from the FIGS. 9 a-h, the size of the crystals increased and the number of grain boundaries was reduced.

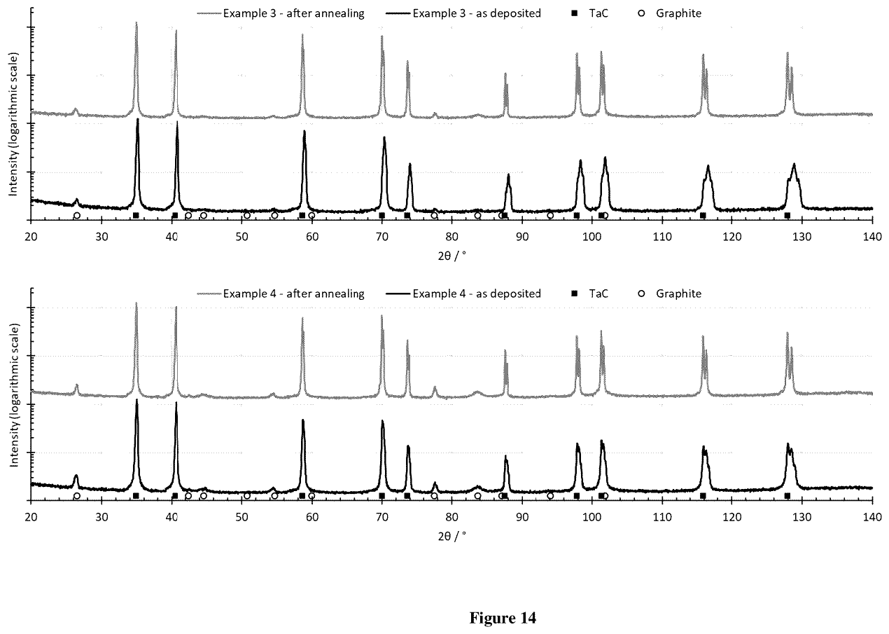

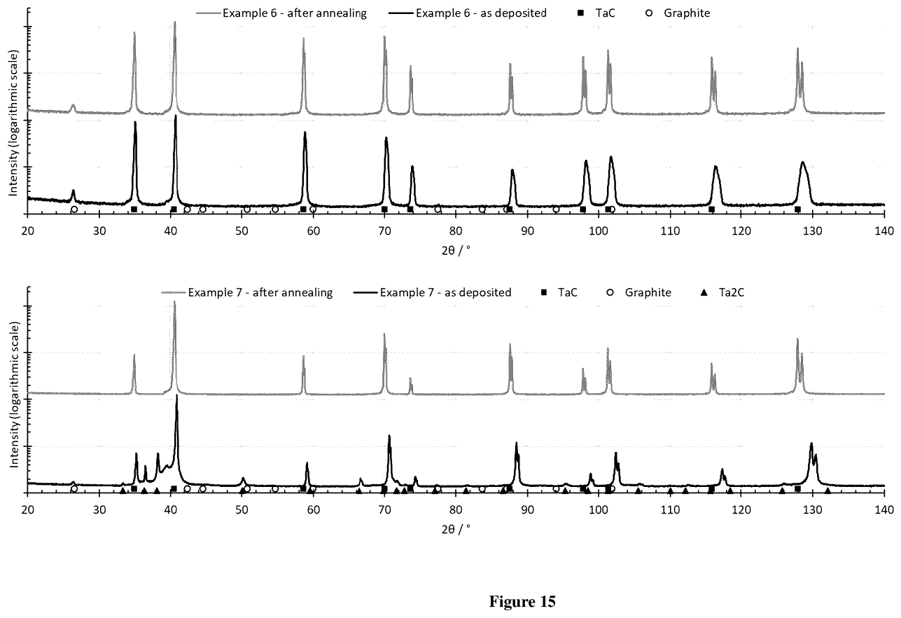

Further, annealing of the samples of the seventh experiment, lead to a conversion of the Ta₂C and Ta species to TaC, resulting in a pure TaC coating. The x-ray diffractometry results after the eighth experiment are shown in FIGS. 14 and 15.

### Ninth Experiment

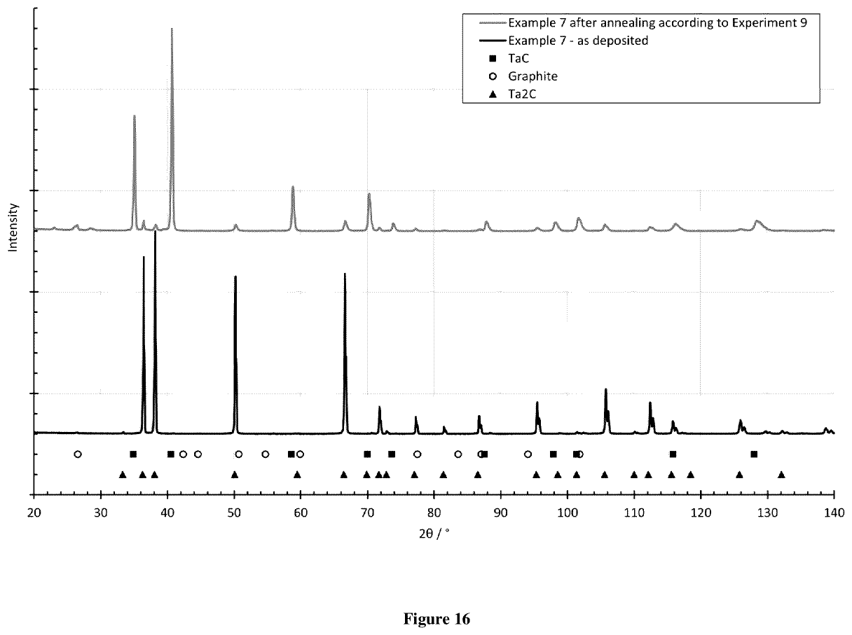

In the ninth experiment the effect of annealing at 1200° C. with an additional carbon source was tested. The samples of the seventh experiment were annealed in an annealing oven for 10 minutes at a temperature of 1200° C. in an Ar and C₂H₄ atmosphere. The flow rate of Ar was 5000 sccm and the flow rate of C₂H₄ was 25 sccm. The annealing led to a conversion of the Ta₂C and Ta species to TaC, resulting in a pure TaC coating. The x-ray diffractometry results of the ninth experiment are shown in FIG. 16.

Although the present invention is defined in the attached claims, it should be understood that the present invention can also (alternatively) be defined in accordance with the following embodiments:
1. A carbonaceous substrate comprising a first tantalum-carbide-coating-layer, wherein the first tantalum-carbide-coating-layer is disposed on an outer surface of the carbonaceous substrate, and wherein the carbonaceous substrate comprises a plurality of pores comprising a tantalum-carbide-pore-coating, wherein the plurality of pores is not completely filled by the tantalum-carbide-pore-coating.
2. The carbonaceous substrate according to any preceding claim, wherein the plurality of pores are disposed less than 182 μm, in particular less than 100 μm from the outer surface.
3. The carbonaceous substrate according to any preceding claim, wherein the tantalum-carbide-pore-coating has a thickness of less than 20 μm, more specifically less than 10 μm and in particular less than 8 μm.
4. The carbonaceous substrate according to any preceding claim, wherein the tantalum-carbide-pore-coating at a depth between about 20 μm to about 60 μm has a thickness between about 0.5 μm to about 8 μm, more specifically between about 0.8 μm to about 3 μm and in particular between about 1 μm to about 2.5 μm.
5. The carbonaceous substrate according to any preceding claim, wherein the ratio between the thickness of the first tantalum-carbide-coating-layer and the tantalum-carbide-pore-coating at a depth between about 20 μm to about 60 μm is between about 2:1 to about 30:1, more specifically between about 3:1 to about 20:1 and in particular between about 5:1 to about 15:1.
6. The carbonaceous substrate according to any preceding claim, wherein the plurality of pores has a maximum diameter between about 5 μm to about 100 μm, more specifically between about 10 μm to about 50 μm and in particular between 15 μm to about 25 μm.
7. The carbonaceous substrate according to any preceding claim, wherein at least 50%, more specifically at least 75% and in particular at least 90% of pores, of the plurality of pores, exhibiting a maximum diameter between about 5 μm to about 100 μm, are not completely filled by the tantalum-carbide-pore-coating.
8. The carbonaceous substrate according to any preceding claim, wherein a volume of the plurality of pores in the carbonaceous substrate is between about 1 vol.-% to about 20 vol.-%, more specifically between about 5 vol.-% to about 15 vol.-% and in particular between about 7 vol.-% to about 13 vol.-%.
9. The carbonaceous substrate according to any preceding claim, wherein the carbonaceous substrate comprises TaC to a penetration depth of at least 20 μm, more specifically at least 40 μm and in particular at least 60 μm.
10. The carbonaceous substrate according to any preceding claim, wherein first tantalum-carbide-coating-layer and/or tantalum-carbide-pore-coating has a ratio of Ta to C of between about 1.3:1 to about 1:1.3, more specifically between about 1.1:1 to about 1:1.1 and in particular between about 1.05:1 to about 1:1.05.
11. The carbonaceous substrate according to any preceding claim, wherein the first tantalum-carbide-coating-layer has a thickness between about 0.1 μm to about 40 μm, more between about 5 μm to about 35 μm and in particular between about 10 μm to about 30 μm.
12. The carbonaceous substrate according to any preceding claim, wherein the first tantalum-carbide-coating-layer comprises the tantalum carbide in the form of tantalum carbide crystals, wherein each tantalum carbide crystal orientation of the group [111], [200], [220], [311] and [311] exhibits a texture coefficient, TCi, of between about 0.5 to about 1.5 which is calculated from maximum peak intensities of an x-ray diffractogram detected with Cu k-alpha radiation at 1.5406 Å wavelength, according to the following formula:

$$T {C}_{i} = \frac{{I}_{i} / {I}_{i , 0}}{( \frac{1}{n} ) {\sum }_{i = 1}^{n} ( {I}_{i} / {I}_{i , 0} )}$$

wherein Iᵢ is selected correspondingly from the maximum intensities of the crystal orientation, wherein n=5 and wherein

| | |
|---|---|
| I₁₁₁ | is the maximum intensity at 2θ ranging from 33.9° to 35.9°, |
| I₂₀₀ | is the maximum intensity at 2θ ranging from 39.4° to 41.4°, |
| I₂₂₀ | is the maximum intensity at 2θ ranging from 57.6° to 59.6°, |
| I₃₁₁ | is the maximum intensity at 2θ ranging from 69.0° to 71.0°, |
| I₂₂₂ | is the maximum intensity at 2θ ranging from 72.6° to 74.6°, |

and wherein I_{í,0} is the expected intensity of the crystal orientation if the crystal orientation of the tantalum carbide crystals was random.
13. The carbonaceous substrate according to any preceding claim, wherein the carbonaceous substrate comprises, essentially consists of or consists of graphite.
14. The carbonaceous substrate according to any preceding claim, wherein the carbonaceous substrate comprises a second tantalum-carbide-coating-layer, wherein the second tantalum-carbide-coating-layer is positioned adjacent to the first tantalum-carbide-coating-layer, in particular wherein the first tantalum-carbide-coating-layer is positioned between the second tantalum-carbide-coating-layer and the outer surface of the carbonaceous substrate.
15. A gas-phase deposition process for coating a carbonaceous substrate with a tantalum carbide coating, wherein the process comprises a coating step, the coating step comprising:
   placing a carbonaceous substrate into a reaction chamber,
   heating the reaction chamber to a temperature between about 1100° C. to about 1500° C. for a duration of between about 1 h to about 24 h,
   supplying a process gas to the reaction chamber, wherein the process gas comprises a halide containing species, wherein for at least 15 min after the start of the process, the process gas comprises less than 4 at.-% of carbon and less than 10 vol.-% of H₂, and supplying a tantalum containing species to the reaction chamber, or placing a solid comprising tantalum into the reaction chamber; or placing a solid comprising a tantalum halide into the reaction chamber.
16. The process according to claim 15, wherein the solid comprising the tantalum comprises tantalum in metallic form, in particular in the form of a tantalum metal powder.
17. The process according to claim 15, wherein the tantalum containing species and the halide containing species are the same, in particular wherein the process gas comprises TaCl₅ and/or other TaClₓ-species.
18. The process according to claim 15, wherein the solid comprising the tantalum halide comprises the tantalum halide in the form of TaCl₅ and/or other TaClₓ-species, in particular in the form of a TaCl₅ and/or a TaClₓ powder.
19. The process according to any preceding claim, wherein the coating step comprises a first and a second coating step, wherein the first coating step is performed at a first temperature and the second coating step at a second temperature, in particular wherein the first temperature is lower than the second temperature.
20. The process according to claim 20, wherein the first temperature is between about 1150 C to about 1250° C. and/or the second temperature is between about 1250° C. to about 1350° C.
21. The process according to any preceding claim, wherein the coating step comprises a third coating step, wherein the third coating step is performed at a third temperature, in particular wherein the third temperature is higher than the first and/or second temperature.
22. The process according to claim 21, wherein the third temperature is at least about 1350° C., more specifically between about 1350° C. to about 1600° C. and in particular between about 1350° C. to about 1450° C.
23. The process according to any one of claim 19 or 20, or 21 to 22 when dependent on claim 18, wherein the duration of each the first and/or second coating step is at least about 15 minutes, more specifically between about 30 minutes to about 120 minutes and in particular between about 45 minutes to about 90 minutes.
24. The process according to claim 21 or 22, wherein the duration of the third coating step is at least about 60 minutes, more specifically at least about 180 minutes and in particular at least about 300 minutes.
25. The process according to any one of claim 19 or 20, or 21 to 24 when dependent on claim 18, wherein the process gas in the first coating step comprises less than 5 at.-%, more specifically less than 1 at.-% and in particular less than 0.1 at.-% carbon, relative to the total number atoms in the process gas.
26. The process according to any one of claim 19 or 20, or 21 to 25 when dependent on claim 18, wherein the process gas in the first coating step comprises less than 4 vol.-%, more specifically less than 1 vol.-% and in particular less than 0.1 vol.-% H₂, relative to the total volume of the process gas.
27. The process according to any one of claim 19 or 20, or 21 to 26 when dependent on claim 18, wherein the process gas in the first coating step comprises halides, in particular chlorine, to carbon in a maximum ratio of 1:0.05, more specifically 1:0.01 and in particular 1:0.001.
28. The process according to any one of claim 19 or 20, or 21 to 27 when dependent on claim 18, wherein the process gas in the first coating step comprises halides, in particular chlorine, to H₂ in a maximum ratio of 1:0.05, more specifically 1:0.01 and in particular 1:0.001.
29. The process according to any one of claim 19 or 20, or 21 to 28 when dependent on claim 18, wherein in the process gas in the second coating step comprises more than 0.1 at.-%, more specifically more than 1 at.-% and in particular more than 5 at.-% carbon, relative to the total number of atoms in the process gas.
30. The process according to any preceding claim, wherein the halide containing species is a chloride containing species, more specifically wherein the chloride containing species is Cl₂ or HCl, and in particular wherein the halide containing species is HCl.
31. The process according to any preceding claim, wherein the process gas additionally comprises an inert gas, more specifically nitrogen or argon and in particular argon.
32. The process according to any preceding claim, wherein the pressure in the reaction chamber is between about 0.001 bar to about 1.1 bar, more specifically between about 0.001 bar to about 0.5 bar and in particular between about 0.1 bar to about 0.2 bar.
33. The process according to any preceding claim, wherein the process additionally comprises an annealing step following the coating step.
34. The process according to claim 33, wherein the annealing step comprises:
   placing the coated carbonaceous substrate into an annealing chamber,
   heating the annealing chamber to a temperature between about 900° C. to about 1800° C. for a duration of between about 10 min to about 5 h,
   supplying a process gas to the reaction chamber, wherein the process gas comprises a carbon containing species, more specifically a carbon and hydrogen containing species, and in particular C₂H₄.
35. The process according to claim 33, wherein the annealing step comprises:
   placing the coated carbonaceous substrate into an annealing chamber,
   heating the reaction chamber to a temperature between about 1900° C. to about 2300° C. for a duration of between about 0.5 h to about 3 h under an inert gas atmosphere.

### Use

36. Use of a carbonaceous substrate according to any one of claims 1 to 14 as a component for epitaxial growth systems, more specifically GaN or SiC-growth systems, and in particular as a wafer carrier for GaN or SiC-growth systems;
   or as a component for physical vapor transport (PVT) systems, more specifically as a component for SiC PVT systems for SiC single-crystal growth and in particular as crucibles or hot walls for PVT systems.

1-15. (canceled)

16. A carbonaceous substrate comprising a first tantalum-carbide-coating-layer,
wherein the first tantalum-carbide-coating-layer is disposed on an outer surface of the carbonaceous substrate,
and wherein the carbonaceous substrate comprises a plurality of pores comprising a tantalum-carbide-pore-coating, wherein the plurality of pores is not completely filled by the tantalum-carbide-pore-coating.

17. The carbonaceous substrate according to claim 16, wherein the tantalum-carbide-pore-coating at a depth between about 20 μm to about 60 μm has a thickness between about 0.5 μm to about 8 μm, more specifically between about 0.8 μm to about 3 μm and in particular between about 1 μm to about 2.5 μm.

18. The carbonaceous substrate according to claim 16, wherein the ratio between the thickness of the first tantalum-carbide-coating-layer and the tantalum-carbide-pore-coating at a depth between about 20 μm to about 60 μm is between about 2:1 to about 30:1, more specifically between about 3:1 to about 20:1 and in particular between about 5:1 to about 15:1.

19. The carbonaceous substrate according to claim 16, wherein at least 50%, more specifically at least 75% and in particular at least 90% of pores, of the plurality of pores, exhibiting a maximum diameter between about 5 μm to about 100 μm, are not completely filled by the tantalum-carbide-pore-coating.

20. The carbonaceous substrate according to claim 16, wherein a volume of the plurality of pores in the carbonaceous substrate is between about 1 vol.-% to about 20 vol.-%, more specifically between about 5 vol.-% to about 15 vol.-% and in particular between about 7 vol.-% to about 13 vol.-%.

21. The carbonaceous substrate according to claim 16, wherein the first tantalum-carbide-coating-layer comprises the tantalum carbide in the form of tantalum carbide crystals, wherein each tantalum carbide crystal orientation of the group [111], [200], [220], and [311] exhibits a texture coefficient, TCᵢ, of between about 0.5 to about 1.5 which is calculated from maximum peak intensities of an x-ray diffractogram detected with Cu k-alpha radiation at 1.5406 Å wavelength, according to the following formula:
$$T {C}_{i} = \frac{{I}_{i} / {I}_{i , 0}}{( \frac{1}{n} ) {\sum }_{i = 1}^{n} ( {I}_{i} / {I}_{i , 0} )}$$
wherein Iᵢ is selected correspondingly from the maximum intensities of the crystal orientation, wherein n=5 and wherein

| | |
|---|---|
| I₁₁₁ | is the maximum intensity at 2θ ranging from 33.9° to 35.9°, |
| I₂₀₀ | is the maximum intensity at 2θ ranging from 39.4° to 41.4°, |
| I₂₂₀ | is the maximum intensity at 2θ ranging from 57.6° to 59.6°, |
| I₃₁₁ | is the maximum intensity at 2θ ranging from 69.0° to 71.0°, |
| I₂₂₂ | is the maximum intensity at 2θ ranging from 72.6° to 74.6°, |

and wherein I_{i,0} is the expected intensity of the crystal orientation if the crystal orientation of the tantalum carbide crystals was random.

22. A gas-phase deposition process for coating a carbonaceous substrate with a tantalum carbide coating, wherein the process comprises a coating step, the coating step comprising:
placing a carbonaceous substrate into a reaction chamber,
heating the reaction chamber to a temperature between about 1100° C. to about 1500° C. for a duration of between about 1 h to about 24 h,
supplying a process gas to the reaction chamber, wherein the process gas comprises a halide containing species, wherein for at least 15 min after the start of the process, the process gas comprises less than 4 at.-% of carbon and less than 10 vol.-% of H₂, and
supplying a tantalum containing species to the reaction chamber, or
placing a solid comprising tantalum into the reaction chamber; or
placing a solid comprising a tantalum halide into the reaction chamber.

23. The process according to claim 22, wherein the tantalum containing species and the halide containing species are the same, in particular wherein the process gas comprises TaCl₅ and/or other TaClₓ-species.

24. The process according to claim 22, wherein the coating step comprises a first and a second coating step, wherein the first coating step is performed at a first temperature and the second coating step at a second temperature, in particular wherein the first temperature is lower than the second temperature.

25. The process according to claim 24, wherein the first temperature is between about 1150 C to about 1250° C. and/or the second temperature is between about 1250° C. to about 1350° C.

26. The process according to claim 24, wherein the duration of each the first and/or second coating step is at least about 15 minutes, more specifically between about 30 minutes to about 120 minutes and in particular between about 45 minutes to about 90 minutes.

27. The process according to claim 24, wherein the process gas in the first coating step comprises less than 5 at.-%, more specifically less than 1 at.-% and in particular less than 0.1 at.-% carbon, relative to the total number atoms in the process gas.

28. The process according to claim 24, wherein the process gas in the first coating step comprises less than 4 vol.-%, more specifically less than 1 vol.-% and in particular less than 0.1 vol.-% H₂, relative to the total volume of the process gas.

29. The process according to claim 22, wherein the pressure in the reaction chamber is between about 0.001 bar to about 1.1 bar, more specifically between about 0.001 bar to about 0.5 bar and in particular between about 0.1 bar to about 0.2 bar.

30. Use of a carbonaceous substrate according to claim 16 as a component for epitaxial growth systems, more specifically GaN or SiC-growth systems, and in particular as a wafer carrier for GaN or SiC-growth systems;
or as a component for physical vapor transport (PVT) systems, more specifically as a component for SiC PVT systems for SiC single-crystal growth and in particular as crucibles or hot walls for PVT systems.
